(19) United States
(12) Patent Application Publication
(10) Pub. No.: US 2007/0138658 A1
(43) Pub. Date: Jun. 21, 2007

(54) Electronic component having an encapsulating compound

(76) Inventors: Alfred Glatz, Sonthofen (DE); Klaus Lerchenmueller, Immenstadt (DE); Gary Toikka, Immenstadt-Buehl (DE)

Correspondence Address: KENYON & KENYON LLP, ONE BROADWAY, NEW YORK, NY, 10004, US

(21) Appl. No.: 11/638,936

(22) Filed: Dec. 13, 2006

(30) Foreign Application Priority Data
Dec. 20, 2005 (DE) 10 2005 060 860.4

(51) Int. Cl. H01L 23/28

(52) U.S. Cl. 257/787

(57) ABSTRACT

An electronic component, in particular an ignition coil, has an encapsulating compound which is formed by a mixture of an A component containing epoxy resin, a flexibilizator, additives, and fillers, and a B component containing at least one curing agent. The flexibilizator is formed from a material from the group of elastic thermoplastics and elastomers and is embedded in an epoxy matrix. To manufacture such an electronic component, the encapsulating compound is formed by mixing the A component with the B component, which contains at least one curing agent and optionally an accelerator, the A component being previously produced by mixing the epoxy resin with the flexibilizator, the additives, and the filler.

### FIELD OF THE INVENTION

The present invention relates to an electronic component, in particular an ignition coil, having an encapsulating compound of the type and a method for its manufacture.

### BACKGROUND INFORMATION

It is known in general that wires or components in electronic components are encapsulated in an encapsulating compound which must withstand extreme conditions and ensure the electrical insulation, medium resistance, and mechanical stability of the component over its entire service life.

In practice, for example, ignition coils are encapsulated using epoxy resins and cured; a distinction may be made between single-component and two-component resin curing systems.

A bisphenol-A encapsulating system, used in practice, represents a two-component resin curing system in particular which, due to its chemical structure, has a glass transition temperature of approximately 135° C. Above this value, the dielectric loss factor increases steeply as a function of the frequency, and thus increasingly and permanently reduces the insulation properties of the molding compound with increasing temperature, promoting its thermal aging.

Due to increasing demands on electric components and their increasingly compact size, ignition coils, in particular when built into the engine, are often exposed to high thermal stresses.

It has been found that the service life of ignition coils may be substantially increased by the use of high-temperature cycloaliphatic epoxy resin-based encapsulating compounds, since glass-transition temperatures considerably higher than 175° C. may be reached with these compounds. However, by using cycloaliphatic epoxy resins, the brittleness and susceptibility to cracking of the molded compound disadvantageously increases considerably, resulting in cracks and thus failure of the component in the event of alternating thermal stresses earlier than when bisphenol-A-based epoxy resins are used.

### SUMMARY OF THE INVENTION

The object of the present invention is to provide an electronic component, in particular an ignition coil, in such a way that the encapsulating compound withstands the thermal stresses, in particular at high temperatures of use, for example, over 135° C., over its entire service life. It is furthermore the object of the present invention to provide a method for manufacturing an electronic component having an encapsulating compound, via which a refractory encapsulating compound may be easily introduced into the electronic component.

The present invention thus provides an electronic component having an encapsulating compound, the encapsulating compound being formed from a mixture of an A component containing epoxy resin, a flexibilizator, additives, and fillers, and a B component containing at least one curing agent. The flexibilizator is formed from a material from the group of elastic thermoplastics and elastomers and is embedded in an epoxy matrix.

The present invention has the advantage that, by using a flexibilizator material from the group of elastic thermoplastics and elastomers, it is possible to flexibilize cycloaliphatic epoxy resins, resulting in low brittleness, susceptibility to cracking, as well as high heat resistance of the encapsulating compound. Tests have shown that the admissible elongation at rupture using a flexibilizator according to the present invention may be increased by a factor of approximately 1.5 to 3 compared to conventional encapsulating compound materials.

An electronic component provided with an encapsulating compound according to the present invention may thus be used at high thermal stresses and have a long service life.

The invention described herein is suitable in particular for use in an ignition coil, but also in general for electric components such as sensors or electronic components exposed to high temperatures and long service lives and which are to be sealed for better heat resistance.

According to an advantageous embodiment of the present invention, the epoxy matrix is formed by a cycloaliphatic epoxy resin; however, the flexibilizator may also be used with a bisphenol-A matrix for improving the flexibility of the encapsulating compound.

A modified, elastic thermoplastic or an elastomer which may be a thermoplastic elastomer or a silicone is suitable as a flexibilizator.

The use of modified silicone which is contained in the A component in a proportion of 2% by weight to 15% by weight has been found advantageous in particular regarding the flexibilization of the encapsulating compound.

### BRIEF DESCRIPTION OF THE INVENTION

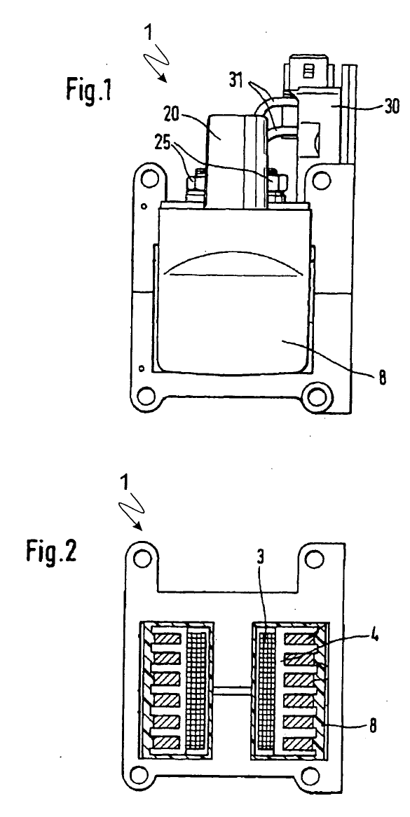

FIG. 1 shows a simplified side view of an ignition coil having an encapsulating compound.

FIG. 2 shows a schematic cross section of an ignition coil of the type depicted in FIG. 1.

### DETAILED DESCRIPTION

The figures of the drawing schematically show the design of an ignition coil 1 as an example of an electronic component. Ignition coil 1 has a primary coil 3 having terminal means 25 for connecting to a low-voltage DC source. Terminal means 25 are connected to output stage 30 via two cables 31, for example. A secondary coil 4 is situated concentrically around primary coil 3 and has terminal means 20 for connection to an ignition distributor or a spark plug, for example. Primary coil 3 and secondary coil 4 are embedded in an encapsulating compound 8.

As an alternative, the ignition coil may also have a rod-shaped design.

To produce encapsulating compound 8, an epoxy resin is mixed with a flexibilizator in a first process step; the flexibilizator must be such that it does not separate from the epoxy resin in the mixture.

The flexibilizator is embedded in the epoxy matrix in a proportion of 2% by weight to 15% by weight, preferably 10% by weight, of the A component made up of the epoxy resin, the flexibilizator, additives, and a filler.

In this case, silicone is used as a flexibilizator that allows the elongation at rupture to be increased by a factor of 1.5 to 3 compared to unmodified solutions.

In a next step, additives, for example, an anti-sedimentation agent or stabilizer, are mixed into the epoxy resin to which a flexibilizator has been added.

Since the epoxy resin has a high coefficient of expansion and is used at temperatures between −50° and 150° C., a filler is added to the epoxy resin to improve its heat resistance, the filler content equaling approximately 50% by weight to 75% by weight of the A component. The filler may have either mineral constituents such as quartz sand, mica, and chalk, or glass beads or glass fibers.

The particle size distribution of the filler is adjusted in such a way that a sufficiently low viscosity of the liquid encapsulating compound 8 is achieved for the encapsulating process, while sedimentation of the filler, which has a higher specific gravity than the epoxy resin, is minimized. A homogeneous mixture which is required for this is achieved by the fact that the filler particles, i.e., particles smaller than approximately 2 μm in this case, are present in at least approximately the same proportion as the coarse particles which in this case are larger than 20 μm. The encapsulating viscosity of liquid encapsulating compound 8 is adjusted to a value smaller than 2000 mPas.

Advantageously, the same curing agents may be used in the present invention as in the case of the known bisphenol-A systems. The curing agent contained in a B component has an anhydride curing agent, in the present preferred embodiment phthalic anhydride, and forms a heat-curing system. An accelerator, whose proportion by weight may be in the range of one-thousandth of the weight of the curing agent, may also be added to make the curing agent react more rapidly with the resin, thus reducing the process times.

In an encapsulating process taking place under vacuum, the proportion of the curing agent is added in accordance with its stoichiometric relationship to the resin, the A component constituting 15% by weight to 40% by weight of the compound as a whole.

Encapsulating compound 8 cast into the ignition coil is then heat cured; it must be ensured that the impregnability of secondary coil 4 is reached, thus avoiding a breakthrough between their secondary windings.

What is claimed is:

1. An electronic component, comprising:
an encapsulating compound formed by a mixture of an A component containing epoxy resin, a flexibilizator, additives, and fillers, and a B component containing at least one curing agent, wherein the flexibilizator is formed from a material from the group of elastic thermoplastics and elastomers and is embedded in an epoxy matrix.

2. The electronic component as recited in claim 1, wherein the epoxy resin is a cycloaliphatic epoxy resin or a bisphenol-A epoxy resin.

3. The electronic component as recited in claim 1,
wherein the elastomer is a thermoplastic elastomer.

4. The electronic component as recited in claim 1,
wherein the elastomer is a silicone.

5. The electronic component as recited in claim 1,
wherein the elastomer is a modified silicone, which is contained in the A component in a proportion of 2% by weight to 15% by weight.

6. The electronic component as recited in claim 5,
wherein the modified silicone is contained in the A component in a proportion of 2% by weight to 10% by weight.

7. The electronic component as recited claim 1,
wherein the proportion of filler particles that are smaller than approximately 2 μm to the particles that are greater than approximately 20 μm is at least approximately the same.

8. The electronic component as recited in one of claim 1,
wherein the filler is contained in the A component in a proportion of 50% by weight to 75% by weight.

9. The electronic component as recited in claim 1,
wherein the filler is made up of mineral constituents such as quartz sand, mica, or chalk.

10. The electronic component as recited in claim 1,
wherein the filler is made up of glass beads or glass fibers.

11. The electronic component as recited in claim 1,
wherein the curing agent is an anhydride curing agent corresponding to phthalic anhydride, and represents a heat-curing system.

12. The electronic component as recited in claim 1, wherein the A component is contained in the encapsulating compound in a proportion of 15% by weight to 40% by weight.

13. The electronic component as recited in claim 1, wherein an accelerator is also added to the B component.

14. The electronic component as recited in claim 1,
wherein the encapsulating viscosity of the encapsulating compound is less than 2000 mPas.

15. A method for manufacturing an electronic component, comprising:
providing an encapsulating compound formed by a mixture of an A component containing epoxy resin, a flexibilizator, additives, and fillers, and a B component containing at least one curing agent, wherein the encapsulating compound is formed by mixing the A component with the B component, which contains at least one curing agent and optionally an accelerator, the A component being previously produced by mixing the epoxy resin with the flexibilizator, the additives, and the filler.

16. The electronic component as recited in claim 1, wherein the electronic component is an ignition coil.
